(19) United States
(12) Patent Application Publication
(10) Pub. No.: US 2018/0143518 A1
(43) Pub. Date: May 24, 2018

(54) PROJECTOR MODULE AND HEAT DISSIPATION ASSEMBLY THEREOF

(71) Applicant: DELTA ELECTRONICS, INC., Taoyuan City (TW)

(72) Inventors: Yi-Ting TSAI, Taoyuan City (TW); Meng-Sheng CHANG, Taoyuan City (TW)

(21) Appl. No.: 15/591,129

(22) Filed: May 10, 2017

(30) Foreign Application Priority Data
Nov. 24, 2016 (TW) 105138600

(51) Int. Cl. G03B 21/16; H05K 7/20; G02B 27/00

(52) U.S. Cl. CPC G03B 21/16; H05K 7/20154; G02B 27/0006; H05K 7/20336; H05K 7/20172; H05K 7/20145

(57) ABSTRACT

A heat dissipation assembly for cooling a rotating heat source includes at least one casing, a blower, and a heat dissipation module. The casing has an accommodating space, a first opening, and a second opening. The first and second openings are in communication with the accommodating space. The rotating heat source is located in the accommodating space. The blower is located on an external surface of the casing and has an air outlet and an air inlet. The air outlet is in communication with the first opening, and the air inlet is in communication with the second opening, such that the accommodating space is closed by the blower. A first part of the heat dissipation module is located in the accommodating space, and a second part of the heat dissipation module is located outside of the casing.

### RELATED APPLICATIONS

This application claims priority to Taiwan Application Serial Number 105138600, Nov. 24, 2016, which is herein incorporated by reference.

### BACKGROUND

### Field of Invention

The present invention relates to a projector module and a heat dissipation assembly of the projector module.

### Description of Related Art

In the projector market today, high brightness and low noise is a trend in the development of the projectors, and heat dissipation for optical elements in light engines is an especially critical technology. For example, the optical element may be a phosphor wheel, a diffuser wheel, a color wheel, etc. In order to prevent dust from entering the light engine of the projector to affect the display quality of the projector, the light engine is usually in a closed design, and heat sinks and fans are disposed outside of a casing of the light engine to increase the heat dissipation area of the light engine and improve thermal convection, thereby reducing the inner temperature of the light engine.

However, along with the increases of the brightness and the power of the light engine, the aforementioned configuration for the light engine with high brightness and high power has not effectively reduced the temperature of the optical element in the light engine.

### SUMMARY

An aspect of the present invention is to provide a heat dissipation assembly for cooling a rotating heat source.

According to an embodiment of the present invention, a heat dissipation assembly includes at least one casing, a blower, and a heat dissipation module. The casing has an accommodating space, a first opening, and a second opening. The first opening and the second opening are in communication with the accommodating space, and the first opening and the second opening are located at different horizontal levels. The rotating heat source is located in the accommodating space. The first opening faces at least a portion of the rotating heat source. The blower is located on an external surface of the casing and has an air outlet and an air inlet. The air outlet is in communication with the first opening, and the air inlet is in communication with the second opening, such that the accommodating space is closed by the blower. The heat dissipation module has a first part and a second part that is physically connected to the first part. The first part of the heat dissipation module is located in the accommodating space, and the second part of the heat dissipation module is located outside of the casing. When airflow flows out of the air outlet of the blower, the airflow passes the rotating heat source and the first part of the heat dissipation module, and then flows into the air inlet of the blower.

In one embodiment of the present invention, the second opening of the casing faces at least a portion of the first part of the heat dissipation module.

In one embodiment of the present invention, a position of the first part of the heat dissipation module is higher than a position of the rotating heat source, and the first part of the heat dissipation module overlaps at least a portion of the rotating heat source.

In one embodiment of the present invention, a position of the air inlet of the blower is higher than a position of the rotating heat source.

In one embodiment of the present invention, the heat dissipation assembly further includes an air guiding member. The air guiding member is located between the first opening of the casing and the air outlet of the blower.

In one embodiment of the present invention, the casing further includes an air guiding part. The air guiding part is located between first opening of the casing and the rotating heat source, and two ends of the air guiding part respectively has the first opening and a third opening that is in communication with the accommodating space, and the third opening faces at least a portion of the rotating heat source.

In one embodiment of the present invention, a top view of the entire heat dissipation module is U-shaped or straight.

In one embodiment of the present invention, the heat dissipation module has a pipe body through the casing, and the pipe body is a heat pipe or a water pipe. The first part of the heat dissipation module includes the pipe body and a first heat sink that are in the accommodating space, and the first heat sink is located on the pipe body.

In one embodiment of the present invention, the second part of the heat dissipation module includes the pipe body and a second heat sink that are located outside the accommodating space, and the second heat sink is located on the pipe body.

In one embodiment of the present invention, the second part of the heat dissipation module further includes a fan device. The fan device is located on the second heat sink.

In one embodiment of the present invention, the second part of the heat dissipation module further includes at least one thermoelectric cooler. The thermoelectric cooler is located on the pipe body outside the accommodating space.

In one embodiment of the present invention, the heat dissipation assembly further includes a dustproof cover. The dustproof cover covers the blower and at least a portion of the casing.

In one embodiment of the present invention, a direction of the air inlet of the blower is perpendicular to an axial direction of the rotating heat source.

In one embodiment of the present invention, a direction of the air inlet of the blower is parallel to an axial direction of the rotating heat source.

Another aspect of the present invention is to provide a projector module.

According to an embodiment of the present invention, a projector module includes a rotating heat source and a heat dissipation assembly. The heat dissipation assembly includes at least one casing, a blower, and a heat dissipation module. The casing has an accommodating space, a first opening, and a second opening. The first opening and the second opening are in communication with the accommodating space, and the first opening and the second opening are located at different horizontal levels. The rotating heat source is located in the accommodating space. The first opening faces at least a portion of the rotating heat source. The blower is located on an external surface of the casing and has an air outlet and an air inlet. The air outlet is in communication with the first opening, and the air inlet is in communication with the second opening, such that the accommodating space is closed by the blower. The heat dissipation module has a first part and a second part that is physically connected to the first part. The first part of the heat dissipation module is located in the accommodating space, and the second part of the heat dissipation module is located outside of the casing. When airflow flows out of the air outlet of the blower, the airflow passes the rotating heat source and the first part of the heat dissipation module, and then flows into the air inlet of the blower.

In the aforementioned embodiment of the present invention, since the blower is located on the external surface of the casing, and the air outlet and the air inlet of the blower are respectively in communication with the first opening and the second opening of the casing, the accommodating space of the casing may be closed by the blower. When the blower is in operation, the blower may form a circulating airflow that passes the rotating heat source and the first part of the heat dissipation module. As a result, the heat of the rotating heat source may be dissipated by the airflow of the blower, and the airflow with high temperature is cooled by the first part of the heat dissipation module, and the cooled airflow returns to the blower and then flows to the rotating heat source again. Through the aforesaid airflow circulation, not only is dust prevented from entering the casing, but also the temperature of the rotating heat source can be effectively reduced.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiments, with reference made to the accompanying drawings as follows:

FIG. 1 is a perspective view of a projector module according to one embodiment of the present invention;

FIG. 2 is a side view of the projector module shown in FIG. 1 after a blower and an air guiding member are removed;

FIG. 3 is a schematic view of the projector module shown in FIG. 1, in which the projector module is in operation;

FIG. 4 is a perspective view of a projector module according to one embodiment of the present invention;

FIG. 5 is a side view of the projector module shown in FIG. 4 after a blower is removed;

FIG. 6 is a schematic view of the projector module shown in FIG. 4, in which the projector module is in operation; and

FIG. 7 is a cross-sectional view of a blower and a casing according to one embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

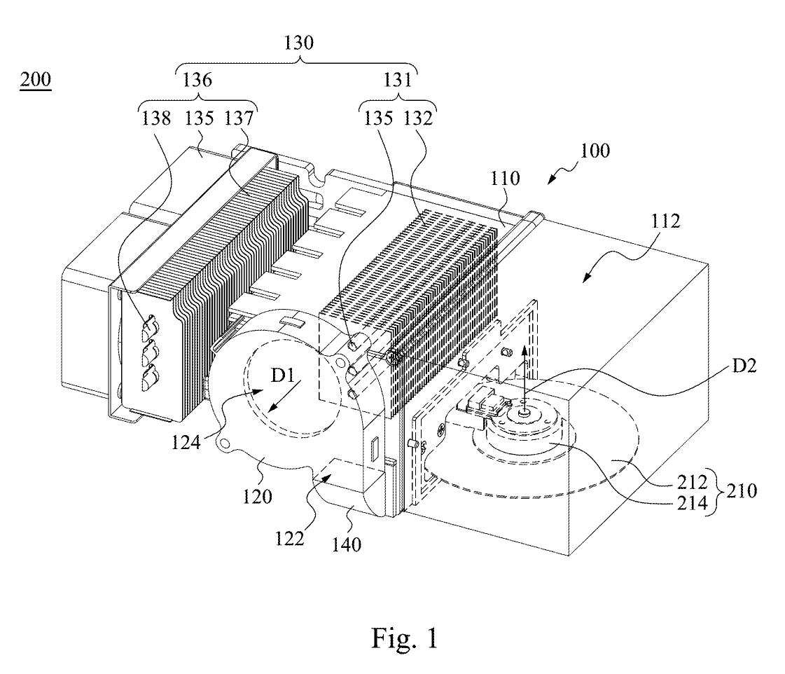

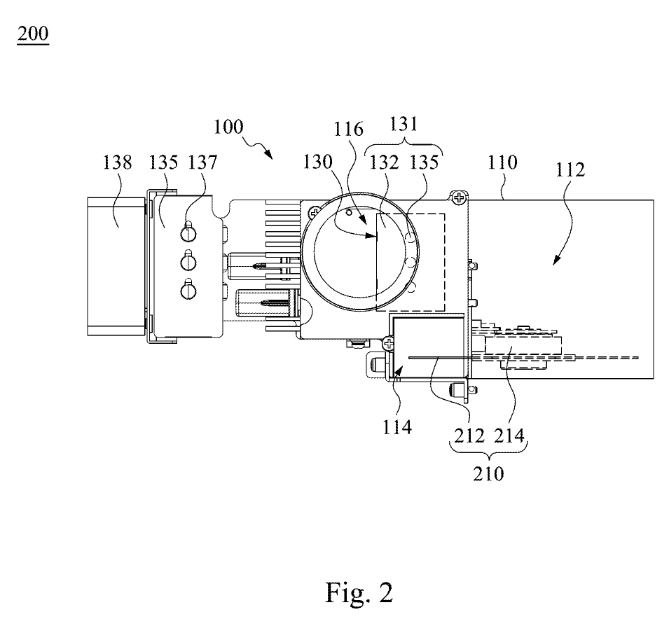

FIG. 1 is a perspective view of a projector module 200 according to one embodiment of the present invention. FIG. 2 is a side view of the projector module 200 shown in FIG. 1 after a blower 120 and an air guiding member 140 are removed. As shown in FIG. 1 and FIG. 2, the projector module 200 includes a rotating heat source 210 and a heat dissipation assembly 100. The heat dissipation assembly 100 may be used to cool the rotating heat source 210. The heat dissipation assembly 100 includes at least one casing 110, the blower 120, and a heat dissipation module 130. The casing 110 has an accommodating space 112, a first opening 114, and a second opening 116. The first opening 114 and the second opening 116 are in communication with the accommodating space 112, and the first opening 114 and the second opening 116 are located at different horizontal levels. In this embodiment, the position of the second opening 116 is higher than the position of the first opening 114 at the casing 110. The rotating heat source 210 is located in the accommodating space 112 of the casing 110. The first opening 114 of the casing 110 faces at least a portion of the rotating heat source 210. The blower 120 is located on an external surface of the casing 110 and has an air outlet 122 and an air inlet 124. The air outlet 122 of the blower 120 is in communication with the first opening 114 of the casing 110, and the air inlet 124 of the blower 120 is in communication with the second opening 116 of the casing 110, such that the accommodating space 112 is closed by the blower 120. In this embodiment, a direction of the air inlet 124 of the blower 120 is perpendicular to an axial direction D2 of the rotating heat source 210, but the present invention is not limited in this regard.

The heat dissipation module 130 has a first part 131 and a second part 136 that is physically connected to the first part 131. The first part 131 of the heat dissipation module 130 is located in the accommodating space 112 of the casing 110, and the second part 136 of the heat dissipation module 130 is located outside of the casing 110. In other words, the heat dissipation module 130 passes through the casing 110 to extend to outside of the casing 110 from the accommodating space 112 of the casing 110.

When projector module 200 is in operation, the rotating heat source 210 may be rotated in the accommodating space 112 of the casing 110 and receives light, such that the temperature of the rotating heat source 210 is increased. The rotating heat source 210 may be a phosphor wheel, a diffuser wheel, or a color wheel, and the present invention is not limited in this regard. The rotating heat source 210 may include a disk 212 and a motor 214, and the motor 214 may drive the disk 212 to rotate. If the rotating heat source 210 is a phosphor wheel capable of receiving a laser, the disk 212 may have transparent regions and phosphor regions.

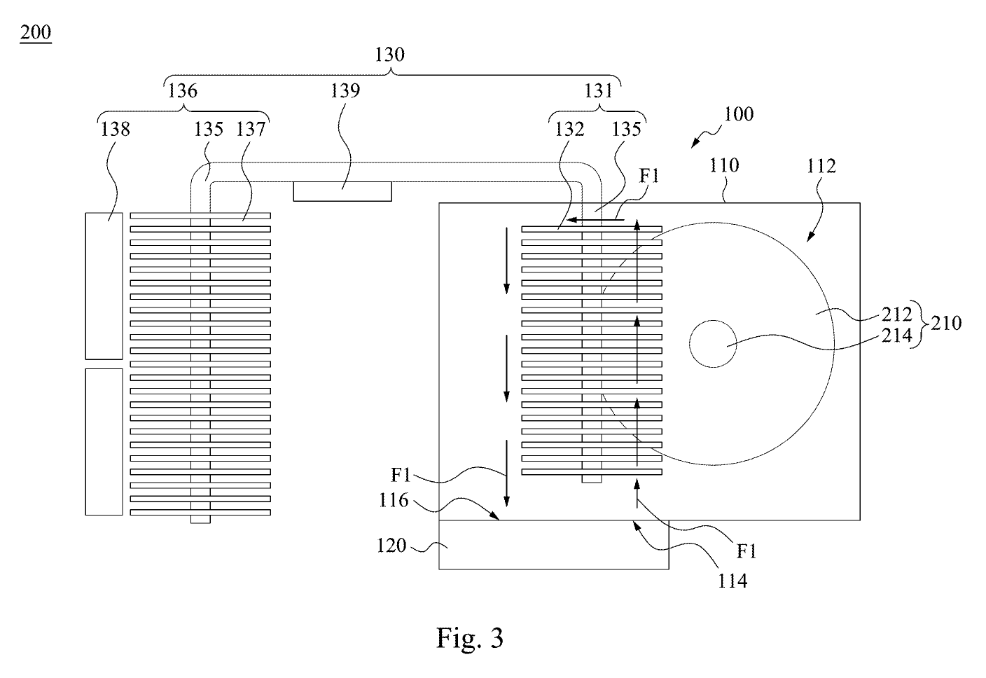

FIG. 3 is a schematic view of the projector module 200 shown in FIG. 1, in which the projector module 200 is in operation. As shown in FIG. 1 and FIG. 3, when the projector module 200 is in operation, the blower 120 is switched on, and the rotating heat source 210 rotates and receives light. The blower 120 forms airflow F1 from the air outlet 122, and then the airflow F1 flows into the accommodating space 112 through the first opening 114 of the casing 110 (also shown in FIG. 2). When the airflow F1 flows from the air outlet 122 of the blower 120, the air inlet 124 of the blower 120 withdraws the airflow F1 at the same time. Therefore, the airflow F1 formed by the blower 120 can pass the rotating heat source 210 and the first part 131 of the heat dissipation module 130, and then flows out of the second opening 116 of the casing 110 (also shown in FIG. 2) to flow into the air inlet 124 of the blower 120. As long as the blower 120 keeps in operation, the aforesaid airflow F1 may circulate repeatedly in the closed accommodating space 112.

As a result, the heat of the rotating heat source 210 may be dissipated by the airflow F1 that is formed by the blower 120, and the airflow F1 with high temperature after passing the rotating heat source 210 may be cooled by the first part 131 of the heat dissipation module 130, such that the airflow F1 with low temperature returns to the blower 120, and then the airflow F1 is blown to the rotating heat source 210 again by the blower 120. Through the aforesaid airflow circulation, not only dust is prevented from entering the casing 110, but also the temperature of the rotating heat source 210 can be effectively reduced. The heat dissipation assembly 100 may reduce the temperature of the disk 212 of the rotating heat source 210 to within 200° C., and may reduce the temperature of the motor 214 to within 85° C.

In this embodiment, a top view of the entire heat dissipation module 130 is U-shaped. However, in another embodiment, a top view of the entire heat dissipation module 130 may be straight, but the present invention is not limited in this regard. The heat dissipation module 130 has a pipe body 135 that is through the casing 110, and the pipe body 135 has a working fluid therein. The pipe body 135 may be a heat pipe or a water pipe as deemed necessary by designers. In the following description, the heat pipe 135 is used as an example. The first part 131 of the heat dissipation module 130 includes the heat pipe 135 and a first heat sink 132 that are in the accommodating space 112. The first heat sink 132 is located on the heat pipe 135 that is in the accommodating space 112. In addition, the second part 136 of the heat dissipation module 130 includes the heat pipe 135 and a second heat sink 137 that are located outside the accommodating space 112. The second heat sink 137 is located on the heat pipe 135 that is located outside of the accommodating space 112. The second part 136 of the heat dissipation module 130 may further include a fan device 138 and at least one thermoelectric cooler 139. The fan device 138 is located on the second heat sink 137, and may form airflow toward the second heat sink 137 to improve the heat dissipation rate of the second part 136 of the heat dissipation module 130, such that the temperature of the accommodating space 112 and the temperature of the rotating heat source 210 may be effectively reduced. The thermoelectric cooler 139 is located on the heat pipe 135 that is located outside the accommodating space 112. The thermoelectric cooler 139 may maintain the first heat sink 132 of the first part 131 of the heat dissipation module 130 in a low temperature state through the heat pipe 135.

In another embodiment, the heat pipe 135 of the heat dissipation module 130 may be replaced with a water pipe of a water-cooling system, and the present invention is not limited in this regard.

In this embodiment, the heat dissipation assembly 100 may further include an air guiding member 140. The air guiding member 140 is located between the first opening 114 (also shown in FIG. 2) of the casing 110 and the air outlet 122 of the blower 120. When the direction of the air outlet 122 of the blower 120 is different from that of the first opening 114 of the casing 110. The hollow air guiding member 140 may be utilized to be in communication with the air outlet 122 of the blower 120 and the first opening 114 of the casing 110.

In addition, the number of the casings 110 may be decided by designers as they deem necessary, and the present invention is not limited in this regard. For example, the casing 110 may include more than two sub-casings that are screwed, fastened, or adhered with each other for assembly convenience.

In this embodiment, the position of the first part 131 of the heat dissipation module 130 is higher than the position of the rotating heat source 210, and the first part 131 of the heat dissipation module 130 overlaps at least a portion of the rotating heat source 210. The position of the air inlet 124 of the blower 120 is substantially the same as the position of the second opening 116 of the casing 110 (also shown in FIG. 2), and is higher than the position of the rotating heat source 210. Moreover, the second opening 116 of the casing 110 faces the first part 131 of the heat dissipation module 130. Such a design may ensure that the airflow F1 entering the first opening 114 passes the rotating heat source 210 under the first part 131 of the heat dissipation module 130 first to dissipate the heat of the rotating heat source 210, and then the airflow F1 passes the first part 131 of the heat dissipation module 130 in an upward direction or a left direction, such that the airflow F1 is withdrawn by the air inlet 124 of the blower 120 after the temperature of the airflow F1 is reduced.

It is to be noted that the connection relationships of the aforementioned elements will not be described again in the following description. In the following description, another type of a projector heat dissipation assembly will be described.

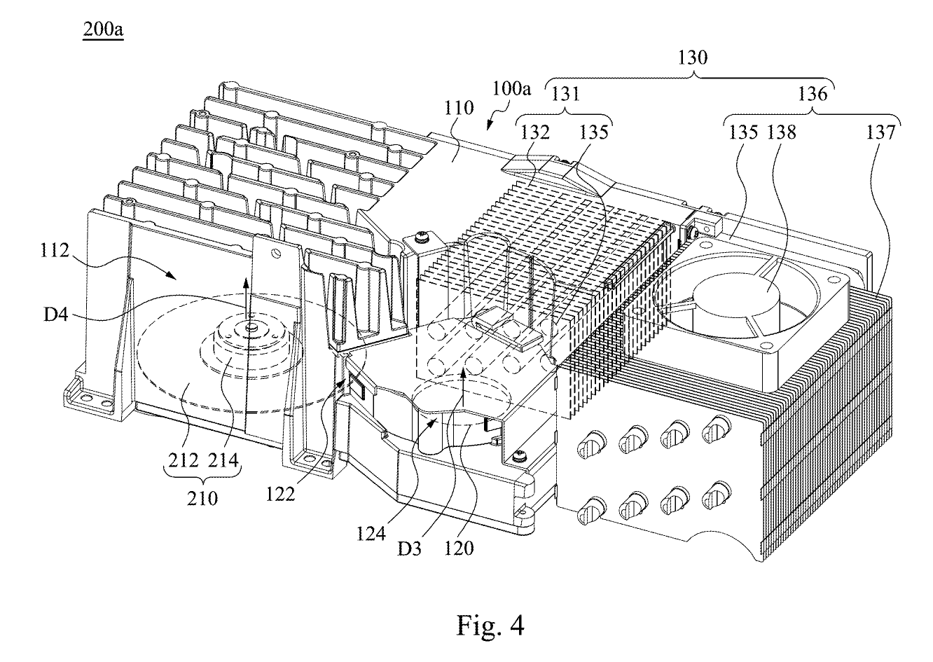

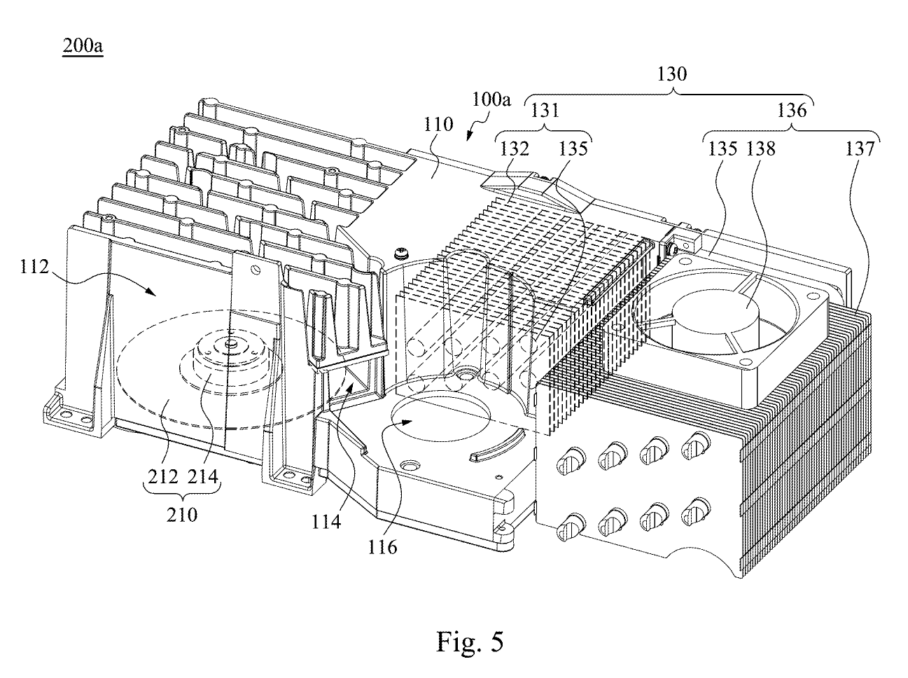

FIG. 4 is a perspective view of a projector module 200a according to one embodiment of the present invention. FIG. 5 is a side view of the projector module 200a shown in FIG. 4 after the blower 120 is removed. As shown in FIG. 4 and FIG. 5, the projector module 200a includes the rotating heat source 210 and a heat dissipation assembly 100a. The heat dissipation assembly 100a includes the casing 110, the blower 120, and the heat dissipation module 130. The blower 120 is located on an external surface of the casing 110 and has the air outlet 122 and the air inlet 124. The air outlet 122 of the blower 120 is in communication with the first opening 114 of the casing 110, and the air inlet 124 of the blower 120 is in communication with the second opening 116 of the casing 110, such that the accommodating space 112 is closed by the blower 120. The difference between this embodiment and the embodiment shown in FIG. 1 is that the position of the second opening 116 is lower than the position of the first opening 114 at the casing 110, and the direction D3 of the air inlet 124 of the blower 120 is parallel to the axial direction D4 of the rotating heat source 210.

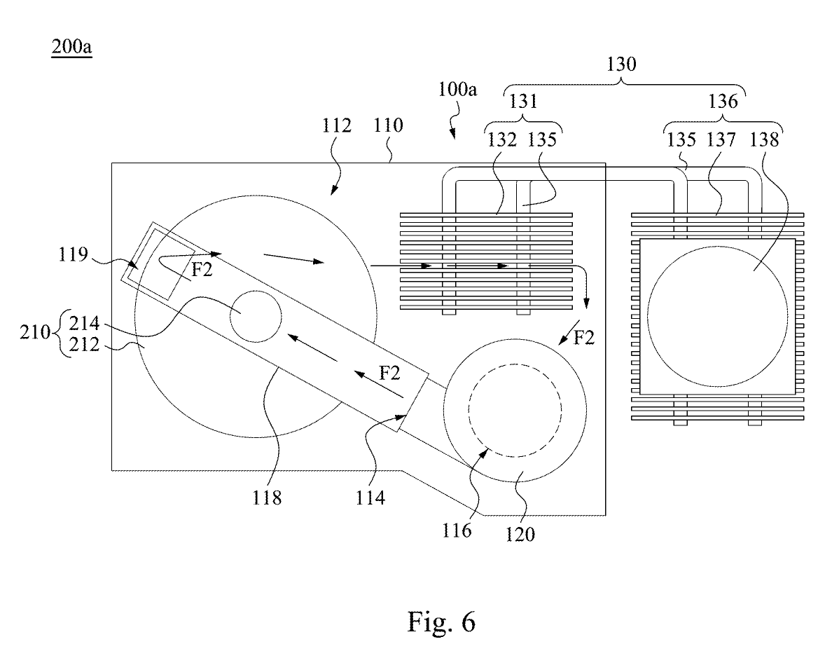

FIG. 6 is a schematic view of the projector module 200a shown in FIG. 4, in which the projector module 200a is in operation. As shown in FIG. 4 and FIG. 6, when the projector module 200a is in operation, the blower 120 is switched on, and the rotating heat source 210 rotates and receives light. The blower 120 forms airflow F2 from the air outlet 122, and then the airflow F2 flows into the accommodating space 112 through the first opening 114 of the casing 110 (also shown in FIG. 5). When the airflow F2 flows from the air outlet 122 of the blower 120, the air inlet 124 of the blower 120 withdraws the airflow F2 at the same time. Therefore, the airflow F2 formed by the blower 120 can pass the rotating heat source 210 and the first part 131 of the heat dissipation module 130, and then flows out of the second opening 116 of the casing 110 (also shown in FIG. 5) to flow into the air inlet 124 of the blower 120.

In this embodiment, the casing 110 may further include an air guiding part 118. The air guiding part 118 is located between first opening 114 of the casing 110 and the rotating heat source 210. Two ends of the air guiding part 118 respectively has the first opening 114 and a third opening 119 that is in communication with the accommodating space 112, and the third opening 119 faces at least a portion of the rotating heat source 210. For example, the third opening 119 may be located above the rotating heat source 210. The air guiding part 118 may receive the airflow F2 that flows out of the air outlet 122 of the blower 120, and guides the airflow F2 toward the rotating heat source 210. The air guiding part 118 may be an element additionally disposed in the casing 110, or may be a portion of the structure of the casing 110, and the present invention is not limited in this regard.

As a result, the heat of the rotating heat source 210 may be dissipated by the airflow F2 that flows from the third opening 119 of the air guiding part 118, and the airflow F2 with high temperature after passing the rotating heat source 210 may be cooled by the first part 131 of the heat dissipation module 130, such that the airflow F2 with low temperature returns to the blower 120, and then the airflow F2 is blown to the rotating heat source 210 again by the blower 120.

In this embodiment, the first part 131 of the heat dissipation module 130 does not overlap the rotating heat source 210, and are spaced apart at a distance. The second opening 116 of the casing 110 (also shown in FIG. 5) is adjacent to the first part 131 of the heat dissipation module 130. The airflow F2 flows into the accommodating space 112 adjacent to the rotating heat source 210 at the third opening 119 by utilizing the air guiding part 118. As a result of such a configuration, the arrangements for the positions of the air outlet 122 and the air inlet 124 of the blower 120 and the positions of the first opening 114 and the second opening 116 of the casing 110 are flexible. Furthermore, the heat dissipation assembly 100a may ensure that the airflow F2 entering the first opening 114 passes the rotating heat source 210 at the left side of the first part 131 of the heat dissipation module 130 first to dissipate the heat of the rotating heat source 210, and then the airflow F2 passes the first part 131 of the heat dissipation module 130 in a right direction, such that the airflow F2 is withdrawn by the air inlet 124 of the blower 120 after the temperature of the airflow F2 is reduced.

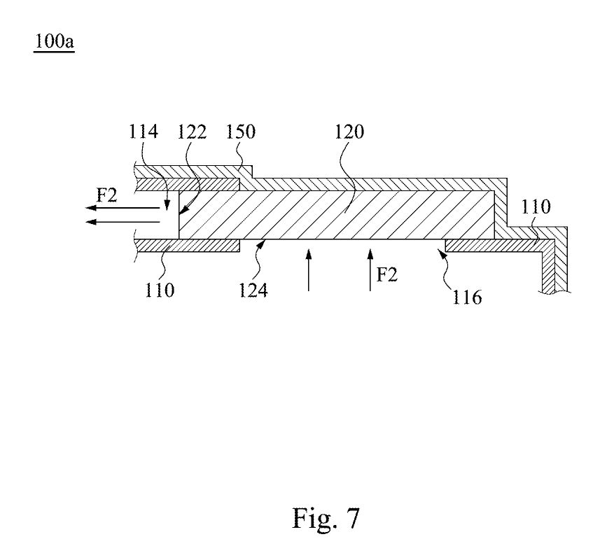

FIG. 7 is a cross-sectional view of the blower 120 and the casing 110 according to one embodiment of the present invention. The heat dissipation assembly 100a of FIG. 4 may further include a dustproof cover 150. The dustproof cover 150 covers the blower 120 and at least a portion of the casing 110. When the dustproof cover 150 covers an external surface of the blower 120 and an external surface of the casing 110 adjacent to the blower 120, the airflow F2 may be prevented from flowing out of a gap between the blower 120 and the casing 110. The dustproof cover 150 may be made of a material including rubber or foam, but the present invention is not limited in this regard.

Similarly, the dustproof cover 150 may be used in the heat dissipation assembly 100 of FIG. 1 to prevent the airflow F1 (see FIG. 3) from flowing out of a gap between the blower 120 and the casing 110.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims.

1. A heat dissipation assembly for cooling a rotating heat source, the heat dissipation assembly comprising:
at least one casing having an accommodating space, a first opening, a second opening, an external surface, and an internal surface opposite the external surface, wherein the first opening and the second opening are in communication with the accommodating space, and the first opening and the second opening are located at different horizontal levels, and the rotating heat source is located in the accommodating space, and the first opening faces at least a portion of the rotating heat source, and the internal surface is proximal to the accommodating space, and the external surface faces away from the accommodating space;
a blower located outside the casing and on the external surface of the casing and having an air outlet and an air inlet, wherein the air outlet is in communication with the first opening, and the air inlet is in communication with the second opening, such that the accommodating space is closed by the blower, and
a heat dissipation module having a first part and a second part that is physically connected to the first part, wherein the first part of the heat dissipation module is located in the accommodating space, and the second part of the heat dissipation module is located outside of the casing, and wherein when an airflow flows out of the air outlet of the blower, the airflow passes the rotating heat source and the first part of the heat dissipation module, and then flows into the air inlet of the blower.

2. The heat dissipation assembly of claim 1, wherein the second opening of the casing faces at least a portion of the first part of the heat dissipation module.

3. The heat dissipation assembly of claim 1, wherein a position of the first part of the heat dissipation module is higher than a position of the rotating heat source, and the first part of the heat dissipation module overlaps at least a portion of the rotating heat source.

4. The heat dissipation assembly of claim 1, wherein a position of the air inlet of the blower is higher than a position of the rotating heat source.

5. The heat dissipation assembly of claim 1, further comprising:
an air guiding member located between the first opening of the casing and the air outlet of the blower.

6. The heat dissipation assembly of claim 1, wherein the casing further comprises:
an air guiding part located between first opening of the casing and the rotating heat source, and two ends of the air guiding part respectively having the first opening and a third opening that is in communication with the accommodating space, and the third opening facing at least a portion of the rotating heat source.

7. The heat dissipation assembly of claim 1, wherein a top view of the entire heat dissipation module is U-shaped or straight.

8. The heat dissipation assembly of claim 1, wherein the heat dissipation module has a pipe body through the casing, and the pipe body is a heat pipe or a water pipe, and the first part of the heat dissipation module includes the pipe body and a first heat sink that are in the accommodating space, and the first heat sink is located on the pipe body.

9. The heat dissipation assembly of claim 8, wherein the second part of the heat dissipation module includes the pipe body and a second heat sink that are located outside the accommodating space, and the second heat sink is located on the pipe body.

10. The heat dissipation assembly of claim 9, wherein the second part of the heat dissipation module further comprises:
a fan device located on the second heat sink.

11. The heat dissipation assembly of claim 9, wherein the second part of the heat dissipation module further comprises:
at least one thermoelectric cooler located on the pipe body outside the accommodating space.

12. The heat dissipation assembly of claim 1, further comprising:
a dustproof cover covering the blower and at least a portion of the casing.

13. The heat dissipation assembly of claim 1, wherein a direction of the air inlet of the blower is perpendicular to an axial direction of the rotating heat source.

14. The heat dissipation assembly of claim 1, wherein a direction of the air inlet of the blower is parallel to an axial direction of the rotating heat source.

15. A projector module, comprising:
a rotating heat source; and
a heat dissipation assembly, comprising:
at least one casing having an accommodating space, a first opening, a second opening, an external surface, and an internal surface opposite the external surface, wherein the first opening and the second opening are in communication with the accommodating space, and the first opening and the second opening are located at different horizontal levels, and the rotating heat source is located in the accommodating space, and the first opening faces at least a portion of the rotating heat source, and the internal surface is proximal to the accommodating space, and the external surface faces away from the accommodating space;
a blower located outside the casing and on the external surface of the casing and having an air outlet and an air inlet, wherein the air outlet is in communication with the first opening, and the air inlet is in communication with the second opening, such that the accommodating space is closed by the blower, and
a heat dissipation module having a first part and a second part that is physically connected to the first part, wherein the first part of the heat dissipation module is located in the accommodating space, and the second part of the heat dissipation module is located outside of the casing, and wherein when an airflow flows out of the air outlet of the blower, the airflow passes the rotating heat source and the first part of the heat dissipation module, and then flows into the air inlet of the blower.

16. The projector module of claim 15, wherein the second opening of the casing faces at least a portion of the first part of the heat dissipation module.

17. The projector module of claim 15, wherein a position of the first part of the heat dissipation module is higher than a position of the rotating heat source, and the first part of the heat dissipation module overlaps at least a portion of the rotating heat source.

18. The projector module of claim 15, wherein a position of the air inlet of the blower is higher than a position of the rotating heat source.

19. The projector module of claim 15, further comprising:
an air guiding member located between the first opening of the casing and the air outlet of the blower.

20. The projector module of claim 15, wherein the casing further comprises:
an air guiding part located between first opening of the casing and the rotating heat source, and two ends of the air guiding part respectively having the first opening and a third opening that is in communication with the accommodating space, and the third opening facing at least a portion of the rotating heat source.

21. The projector module of claim 15, wherein a top view of the entire heat dissipation module is U-shaped or straight.

22. The projector module of claim 15, wherein the heat dissipation module has a pipe body through the casing, and the pipe body is a heat pipe or a water pipe, and the first part of the heat dissipation module includes the pipe body and a first heat sink that are in the accommodating space, and the first heat sink is located on the pipe body.

23. The projector module of claim 22, wherein the second part of the heat dissipation module includes the pipe body and a second heat sink that are located outside the accommodating space, and the second heat sink is located on the pipe body.

24. The projector module of claim 23, wherein the second part of the heat dissipation module further comprises:
a fan device located on the second heat sink.

25. The projector module of claim 23, wherein the second part of the heat dissipation module further comprises:
at least one thermoelectric cooler located on the pipe body outside the accommodating space.

26. The projector module of claim 15, further comprising:
a dustproof cover covering the blower and at least a portion of the casing.

27. The projector module of claim 15, wherein a direction of the air inlet of the blower is perpendicular to an axial direction of the rotating heat source.

28. The projector module of claim 15, wherein a direction of the air inlet of the blower is parallel to an axial direction of the rotating heat source.
